(19) United States
(12) Patent Application Publication
(10) Pub. No.: US 2015/0026545 A1
(43) Pub. Date: Jan. 22, 2015

(54) SYSTEM AND METHOD FOR GENERATING CONSTELLATION-BASED INFORMATION CODING USING PHYSICAL NOISY PSEUDO-RANDOM SOURCES

(71) Applicant: Verayo, Inc., San Jose, CA (US)

(72) Inventors: Meng-Day Mandel YU, Fremont, CA (US); Srinivas DEVADAS, Lexington, MA (US)

(21) Appl. No.: 14/335,858

(22) Filed: Jul. 18, 2014

Related U.S. Application Data
(60) Provisional application No. 61/847,836, filed on Jul. 18, 2013.

(51) Int. Cl. H04L 1/00; H03M 13/03; H03K 19/003

(52) U.S. Cl. CPC H04L 1/0042; H03K 19/00369; H03M 13/03
USPC 714/780

(57) ABSTRACT

A method and system are provided for a symbol-oriented approach that addresses information recovery from manufacturing variations (MVs) readings in a high noise environment. The multi-bits-per-symbol approach, which is in accordance with the various aspects of the present invention, is in contrast with how manufacturing-variation-derived bits are normally treated in the context of PUF Key Generation's error correction process. The multi-bit-per-symbol approach also offers a natural distance metric (distance to the most-likely symbol, distance to the next-most-likely symbol, etc.) which can aid soft-decision decoding or list-decoding, and can be used to improve the provisioning of a more reliably encoded secret and its associated helper data value.

### CROSS-REFERENCE TO RELATED APPLICATION

This application claims priority, under 35 USC 119, from U.S. Provisional Application No. 61/847,836 filed on Jul. 18, 2013 and titled SYSTEM AND METHOD FOR GENERATING CONSTELLATION-BASED INFORMATION CODING USING PHYSICAL NOISY PSEUDO-RANDOM SOURCES, the entire disclosure of which is incorporated herein by reference. This application is related to and, hence, incorporates by reference the disclosure of U.S. Provisional Application No. 61/767,105 filed on Feb. 20, 2013 and titled USING ENTITY AUTHENTICATION PROPERTIES OF NOISY PHYSICAL FUNCTIONS FOR DATA INTEGRITY PROTECTION AND DATA CONFIDENTIALITY.

### FIELD OF THE INVENTION

The present invention relates to security in association with semiconductors and, more specifically, to using physical noisy pseudo-random sources, for example, arising from manufacturing variations, to code information bits, using a constellation-based symbol-oriented (vs. a bit-oriented) technique to enable a higher level of noise tolerance associated with factors such as environmental stresses or noisy manufacturing processes.

### BACKGROUND

This invention relates to the use of physical noisy pseudo-random sources, for example, arising from manufacturing variations, to code information bits, using a constellation-based symbol-oriented (vs. a bit-oriented) technique which has uses when Physical Uncolnable Functions (PUFs) are used to generate keys and for authentication. The following references are cited and incorporated herein:
1. B. Gassend, D. Clarke, M. van Dijk, S. Devadas, “Silicon Physical Random Functions”, Proc. Computer and Communication Security Conference (CCS), November 2002.
2. B. Gassend, D. Clarke, M. van Dijk, S. Devadas, “Controlled Physical Random Functions”, Proc. Computer Security Applications Conference, December 2002.
3. G. Suh, C. O'Donnel, I. Sachdev, S. Devadas, “Design and Implementation of the AEGIS Secure Processor Using Physical random Functions”, Prof. Int'l Symposium on Computer Architecture, June 2005.
4. G. Suh, S. Devadas, “Physical Unclonable Functions for Device Authentication and Key Generation”, Prof. Design Automation Conference (DAC), June 2007.
5. M. Yu, S. Devadas, “Secure and Robust Error Correction for Physical Unclonable Functions”, IEEE Design and Test of Computers, Special Issue on Verifying Physical Trustworthiness of ICs and Systems, vol. 27, no. 1, pp. 48-65, January/February 2010.
6. M. Yu, S. Devadas, “Recombination of Physical Unclonable Functions”, Government Microcircuit Applications and Critical Technology Conference (GOMAC), March 2010.
7. Z. Paral, S. Devadas, “Reliable and Efficient PUF-based Key Generation Using Pattern Matching”, IEEE Hardware-Oriented Security and Trust (HOST) conference, June 2011.
8. M. Yu, D. M'Raihi, R. Sowell, S. Devadas, “Lightweight and Secure PUF Key Storage Using Limits of Machine Learning”, Cryptographic Hardware and Embedded Systems (CHES) 2011, Lecture Notes in Computer Science (LNCS) 6917, pp. 358-373.
9. M. Yu, R. Sowell, A. Singh, D. M'Raihi, S. Devadas, “Performance Metrics and Empirical Results of a PUF Cryptographic Key Generation ASIC”, IEEE International Symposium on Hardware-Oriented Security and Trust (HOST), 2012.

### SUMMARY

A method and system are provided for a symbol-oriented approach that addresses information recovery using manufacturing variations (MVs) in a high noise environment. The multi-bits-per-symbol approach, which is in accordance with the various aspects of the present invention, is in contrast with how manufacturing-variation-derived bits are normally treated in the context of PUF Key Generation's error correction process, where each PUF bit is treated effectively as a single-bit symbol (vs. a multi-bit symbol) to form an error correction codeword. The multi-bit-per-symbol approach also offers a natural distance metric (distance to the most-likely symbol, distance to the next-most-likely symbol, etc.) which can aid soft-decision decoding or list-decoding, and can be used to improve the provisioning of a more reliably encoded secret and its associated helper data value.

When the various aspects of the present invention are applied to silicon Physical Unclonable Function (PUF), this turns into a method of PUF key generation where keying bits can be embedded inside manufacturing variations in environments or manufacturing processes that has a high level of noise, and in some cases exceeding noise level that can be error corrected using conventional single-stage error correction techniques with a bit-oriented codeword using the popular code-offset method. Therefore, what is needed is a symbol-oriented approach that addresses key recovery from manufacturing variations in a high noise environment.

Information bits are divided into multi-bit symbols (with single bit symbol being a degenerate case). Each symbol is mapped onto manufacturing variation readings and later recovered from another reading of the manufacturing variations. In regular communication systems, symbols are modulated onto “I” and “Q” signals in the form of sine and cosine waves, e.g., 1 bit encoded in a BPSK constellation, 2 bits encoded in a QPSK constellation, 8 bits in a QAM-256 constellation. In our case, each symbol is mapped onto manufacturing variations readings, where two possible selections of manufacturing-variation-derived readings are available for a 1-bit symbol, four possible selections of manufacturing-variation-derived readings are available for a 2-bit symbol, 256 possible selections of manufacturing-variation-derived readings are available for an 8-bit symbol, etc. The selection can be based on aspects such has PUF challenge selection, PUF response selection, or PUF circuit selection, or combinations of these or other manipulatable attributes. More generally, the challenge is a function (with “selection” of a starting challenge being a simple function) of a symbol to be mapped, the response is a function of a symbol to be mapped (with “selection” of a response scrambling code being a simple function), or the PUF circuit choice is a function of a symbol to be mapped (with “selection” of a PUF circuit being a simple function).

### BRIEF DESCRIPTION OF THE DRAWINGS

FIG. 1A shows a constellation mapping example using PUF circuit selection in accordance with various aspects of the present invention.

FIG. 1B shows a constellation mapping example using PUF response selection in accordance with various aspects of the present invention.

FIG. 1C shows a constellation mapping example using PUF challenge selection in accordance with various aspects of the present invention.

FIG. 2 shows mapping of multiple symbols using multiple blocks of PUF response readings and uses PUF circuit selection in accordance with various aspects of the present invention.

FIG. 3 shows recovery of multiple symbols using multiple blocks of PUF response readings and uses PUF circuit selection and maximum likelihood detection to determine the most likely PUF circuit selection in accordance with various aspects of the present invention.

FIG. 4 shows key provisioning process wherein a manufacturing variation (MV) block and a constellation mapping block (CMAP) is iterated over multiple symbols to produce multiple blocks of helper data and a downmix function (DMIX) (e.g., hash) is added to downmix the symbol bits into a key in accordance with various aspects of the present invention.

FIG. 4B shows FIG. 4 with error correction encoding operating in a symbol-oriented (vs. a bit-oriented) fashion in accordance with various aspects of the present invention.

FIG. 5 shows a key regeneration process where the MV block and a constellation recovery block (CRECOVERY) is iterated over multiple blocks of helper data to recover the original symbols and a DMIX (e.g., hash) is added to downmix the symbol bits into a key in accordance with various aspects of the present invention.

FIG. 5B shows FIG. 5 with error correction decoding operating in a symbol-oriented (vs. a bit-oriented) fashion in accordance with various aspects of the present invention.

### DETAILED DESCRIPTION

Traditional PUF Key Generation methods perform reliability so long as a noisy regenerated response decodes to the legitimate single error correction codeword that was provisioned. Specifically, the environmental and physical noise of the physical noisy pseudo-random source cannot deviate beyond the hamming sphere of the legitimate code-word. Using a traditional single-stage error correction code such as a BCH code, this correspond an asymptotic limit of 25% of the response size. For a 256-bit response, this means that no more than 64 bits of noise can be present (i.e., no more than 64 bits can be flipped due to environmental variations such as voltage, temperature, or aging, or due to physical noise factors). Otherwise, the noisy response may get decoded into an adjacent code-word that is incorrect.

In accordance with various aspects of the present invention, a maximum likelihood and optionally a list-decoding approach of secret keying bits mapped to a constellation is disclosed. In accordance with various aspects, the system allows for reliable decoding and keying bits recovery beyond the 25% limit of traditional single stage error correction approaches. In fact, under certain configurations based on the aspects of the present invention, the error correction can approach a 50% limit. For example and in accordance with an aspect of the present invention, two responses each of 256-bits are derived from two different physical noisy pseudo-random sources on the same device. On the average, these two response bits would have 128-bits that are different. So long as the regenerated response doesn't deviate so much as to cross the mid-point boundary (50% limit) between the two, the secret bit can be reliably decoded. In a configuration based on one aspect, where there are multiple responses, a list decoding approach can be used so that decoding to adjacent constellation points can be detected and thus still allow for reliable secret keying bits recovery using an additional error detection or error control mechanism.

The scope of the present invention is not limited by the application to a specific field. For example, the present invention and its various aspects can be used to secure booting of a computer that uses an ARM processor, to generate secure keys for smart cards, or to generate keys for secure tokens.

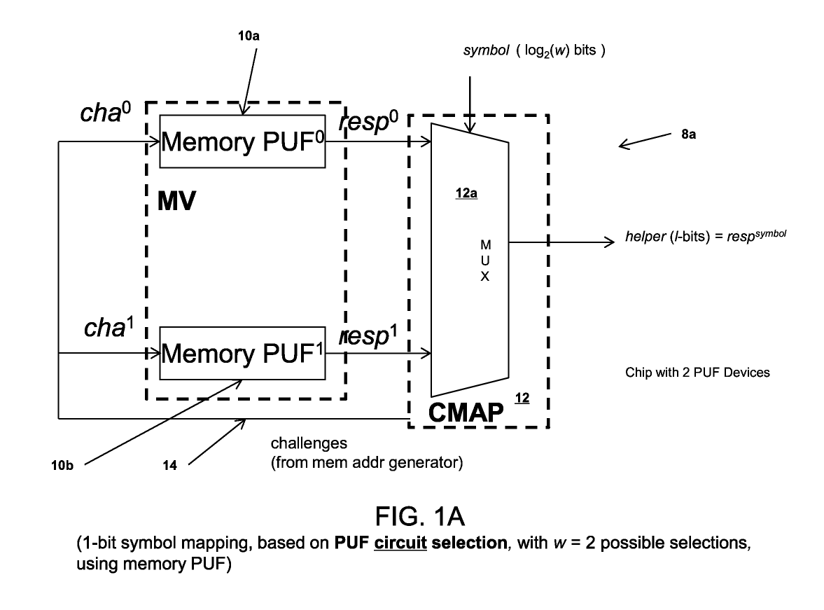

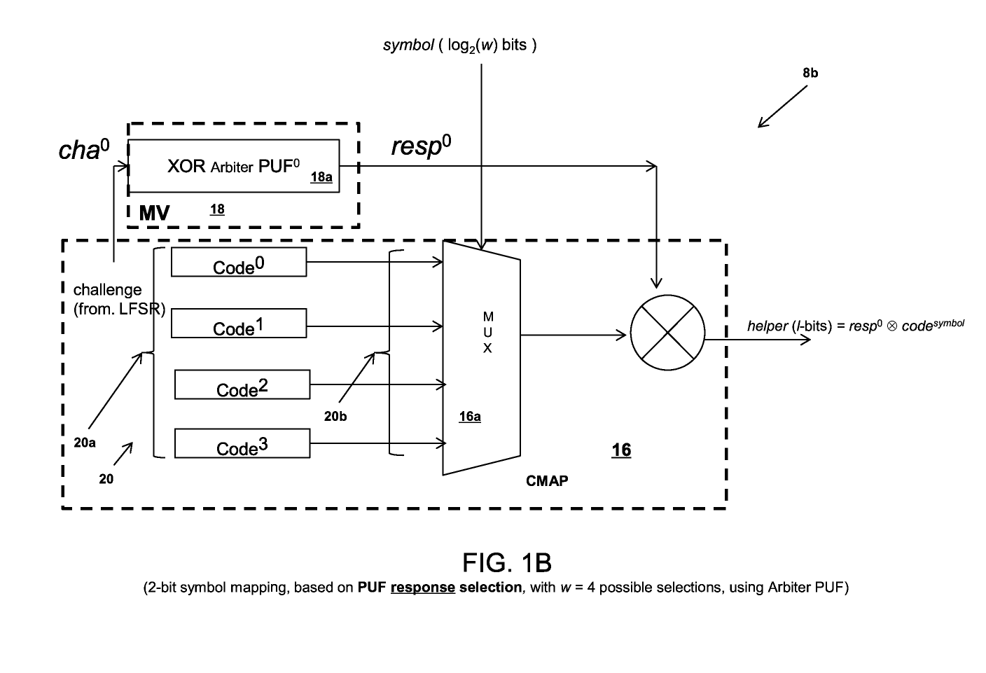

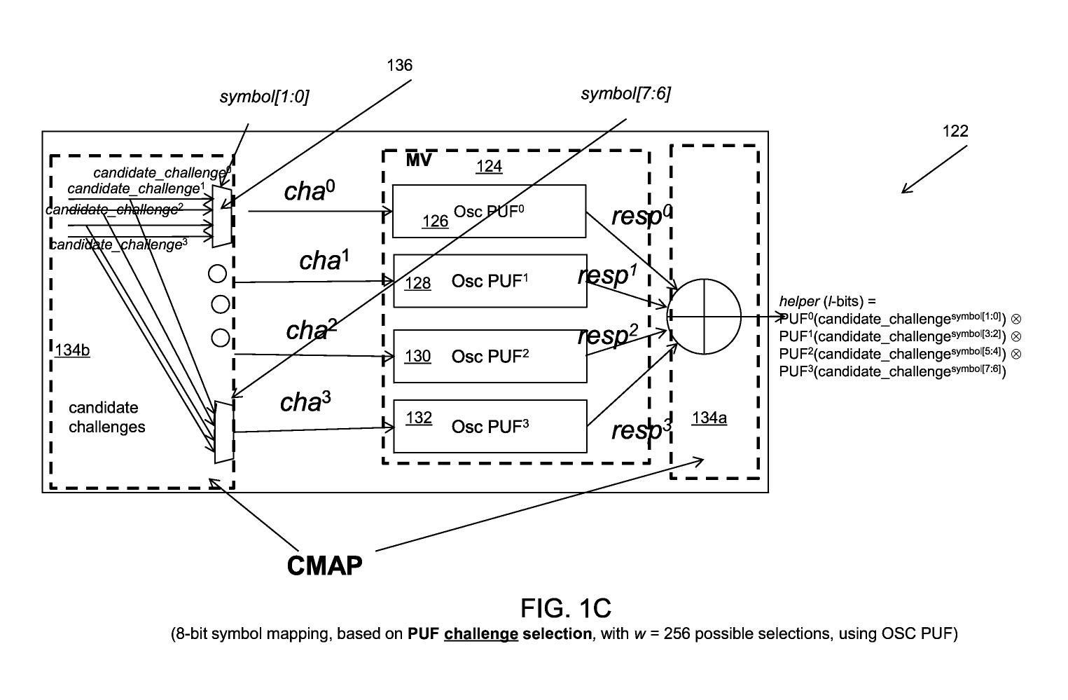

Referring now to FIG. 1A, in accordance with some aspects of the present invention, a system or chip 8a is shown for symbol mapping based on selection of a PUF circuit, for example a memory PUF circuit whose output readings depend on uninitialized 6T SRAM memory values available upon initial power-up, where the binary readings depend on the manufacturing variations of each 6T cell's bi-stable circuit, and more specifically, the manufacturing mismatch of the bi-stable back-to-back inverter readback. The system 8a comprises two modules, units, or blocks: the manufacturing variation unit 10, which includes one or more PUFs, such as PUFs 10a and 10b and a constellation mapper unit (CMAP) 12, which includes a multiplexer (MUX) 12a. The MVU 10 represents manufacturing variation block, comprising of one or more PUF circuits. Specifically, a 1-bit symbol is mapped onto readings from a manufacturing variation unit (MVU) 10 using a selection of two instances of PUF circuits or PUFs 10a and 10b. In accordance with various aspects of the present invention, the system 8 is shown with two silicon PUFs 10a and 10b, on the MVU 10, as PUF⁰ and PUF¹, respectively. For a given challenge applied to both PUFs 10a and 10b (or more generally for two different but predictably scheduled challenges applied to both circuits), two strings of response bits are generated.

In FIG. 1A, an example using PUF 10a and 10b is shown and the challenges can be memory addresses in accordance with various aspects of the present invention. CMAP 12 represents the constellation mapping block, in this case a simple 2:1 multiplexer 12a and a memory address (challenge) generator 14 that can be as simple as an incrementing address counter. The two PUFs 10a and 10b can also be implemented as a single memory, in accordance with various aspects of the present invention, where partitioned (e.g., the upper and lower or odd/even) memory regions are compared.

Referring now to FIG. 1 B, in accordance with one aspect, symbol mapping is based on PUF response selection. Specifically, a system or chip 8b is shown wherein a 2-bit symbol is mapped onto manufacturing variation readings provided by an MVU 18 using a selection of four scrambled code choices 20 (resulting in one of four scrambled response values) using an XOR Arbiter PUF 18a (the Arbiter PUF produces responses based on an input challenge which configures a parallel race condition, where the “winner” of the race condition depends on manufacturing variations). The system 8b comprises, in accordance with various aspects of the present invention, two modules, units, or blocks: the MVU 18 comprising one or more PUFs 18a and a CMAP 16, which acts as a constellation mapper. In particular, the system 8b is shown with a silicon XOR Arbiter PUF 18a and denoted PUF². One of four scrambling codes 20a (e.g., m-sequences or walsh code, which can be represented and implemented compactly, and with large minimum distances) is applied so that one of four (scrambled) response choices is selected through a choice of 20b based on the 2-bit symbol to be mapped. MVU 18 represents a manufacturing variation block. The CMAP 16 represents the constellation mapping unit or block, in this case a simple 4:1 multiplexer 16a and a challenge generator, which can be an LFSR, with a primitive polynomial with a fixed initial value.

Referring now to FIG. 1C, in accordance with various aspects of the present invention, symbol mapping that is based on PUF challenge selection is shown. Specifically, an 8-bit symbol is mapped onto manufacturing variation readings from a MVU 124 using a selection of four possible challenges across four Oscillator (OSC) PUFs 126, 128, 130, and 132 in a recombinatorial arrangement whose output is XORed (the OSC PUF produces responses based on manufacturing variations that cause identically place-and-routed ring oscillators to produce different oscillation frequencies). A system 122 comprises two modules, units, or blocks: the MVU 124 that includes one or more PUFs 126, 128, 130, and 132 and a CMAP 134, a constellation mapper. In particular, a system or chip is shown with four silicon OSC PUFs 126, 128, 130, and 132, which are denoted as PUF⁰, PUF¹, PUF², and PUF^{3,}, respectively. In accordance with various aspects of the present invention this example, each of the OSC PUF is the recombinatorial variety. One of four challenge selection is applied to each OSC PUF 126, 128, 130, and 132. Each PUF can encode two bits so a total of 8 bits can be encoded (the four OSC PUF results are XORed). The MVU 124 produces manufacturing variations readings. The CMAP 134 represents the constellation mapping block, in this case a simple four 4:1 multiplexer 136 for challenge selection and an XOR function, as well as a fixed challenge generator that can be four LFSRs with primitive polynomial with initial values to generate four challenge choices. In accordance with various aspects of the present invention, a single LFSR can be used and four XOR masks can be individually applied to the LFSR parallel output, or the four challenges can be generated from a single LFSR at different points in time.

As can be inferred from FIG. 1A, FIG. 1B, and FIG. 1C, more generally, helper data is a function of the MVUs that produce the manufacturing variation characteristics and the input symbol and may include one or more of the following: (i) a plurality of challenges; (ii) a plurality of responses choices; and (iii) a plurality of PUF circuits.

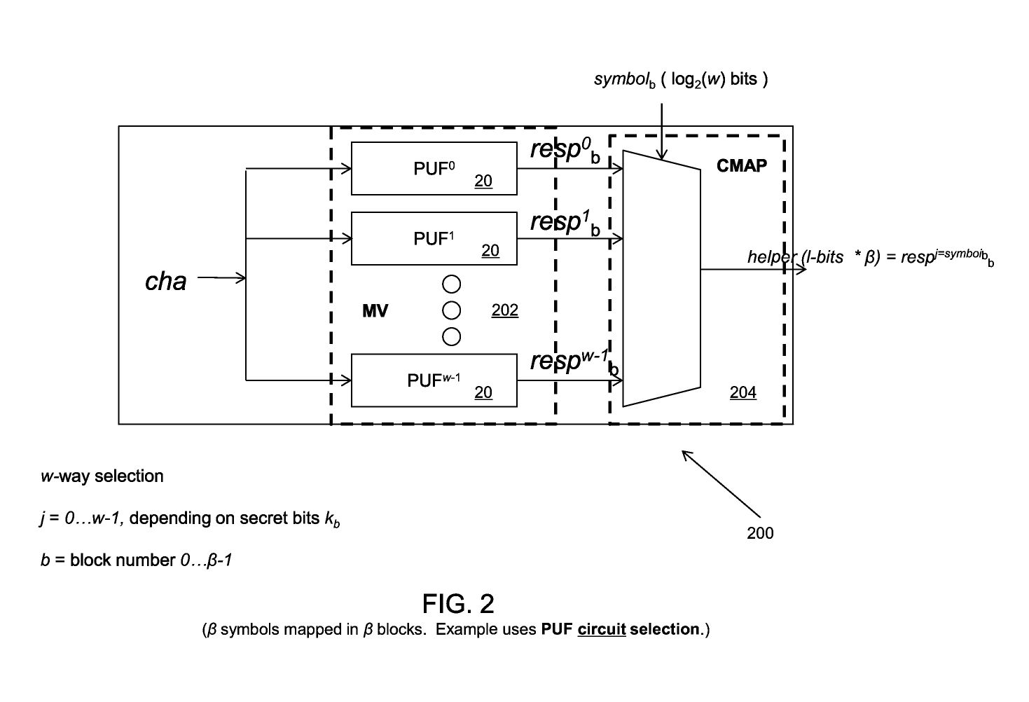

Referring now to FIG. 2 that shows a system 200 for mapping multiple symbols. The system 200 includes an MVU 202 and a CMAP 204. The MVU 202 includes PUFs 20. In accordance with various aspects of the present invention, the system 200 uses PUF selection. There are β symbols to be mapped. Each mapped symbol is based on a selection of w PUFs 204. Thus, each symbol is log₂(w) bits and a total of β×log₂(w) bits are mapped. Each symbol is mapped onto an I-bits (e.g., I of 128 bits) response block inside the CMAP 204, and this occurs β times. So each PUF 204 generates β response blocks of data.

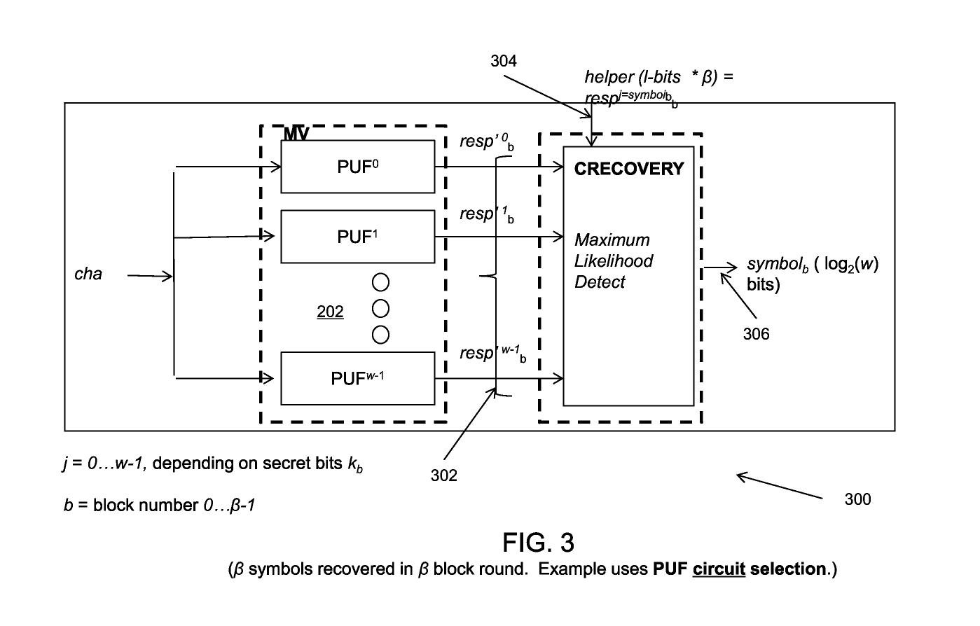

Referring now to FIG. 3, in accordance with various aspects of the present invention a system 300 is shown. The system 300 recovers the original symbol selection of FIG. 2. The system 300 uses a maximum likelihood detection method in accordance with various aspects of the present invention. The system 300 can be used to determine the candidate responses 302 with the highest correlation (greatest number of matching bits) to the helper data 304 (a response output from CMAP) in order to recover a symbol 306, which is the original symbol. It can be shown that the maximum likelihood detection recovery is the most optimal decoder if the original symbol inputs are uniformly distributed, meaning that this is the most optimal decoder possible to recover the symbols.

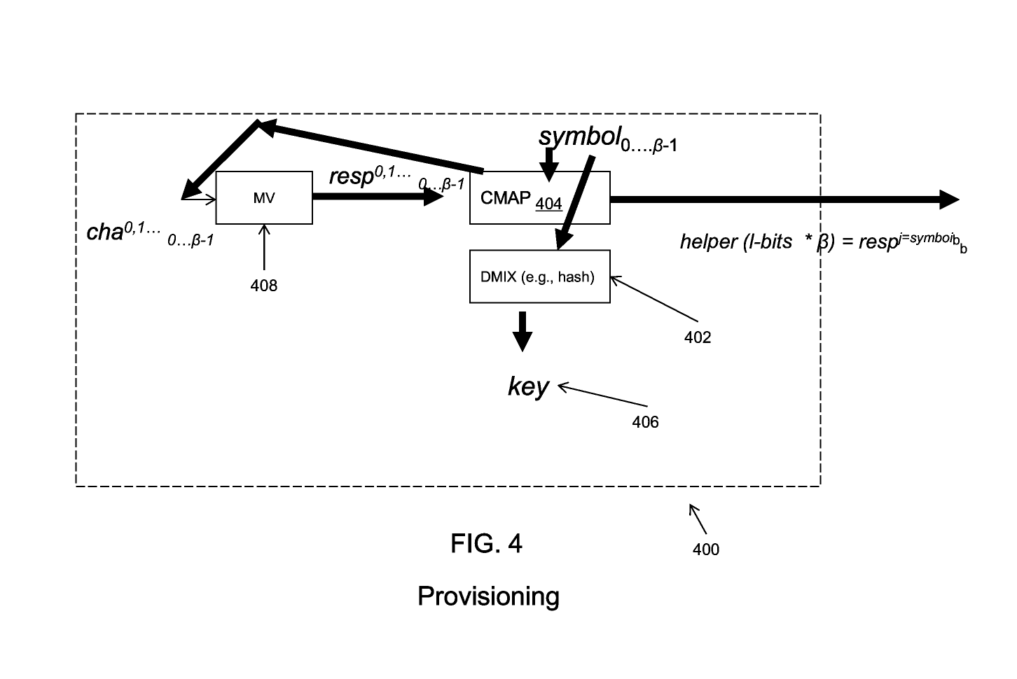

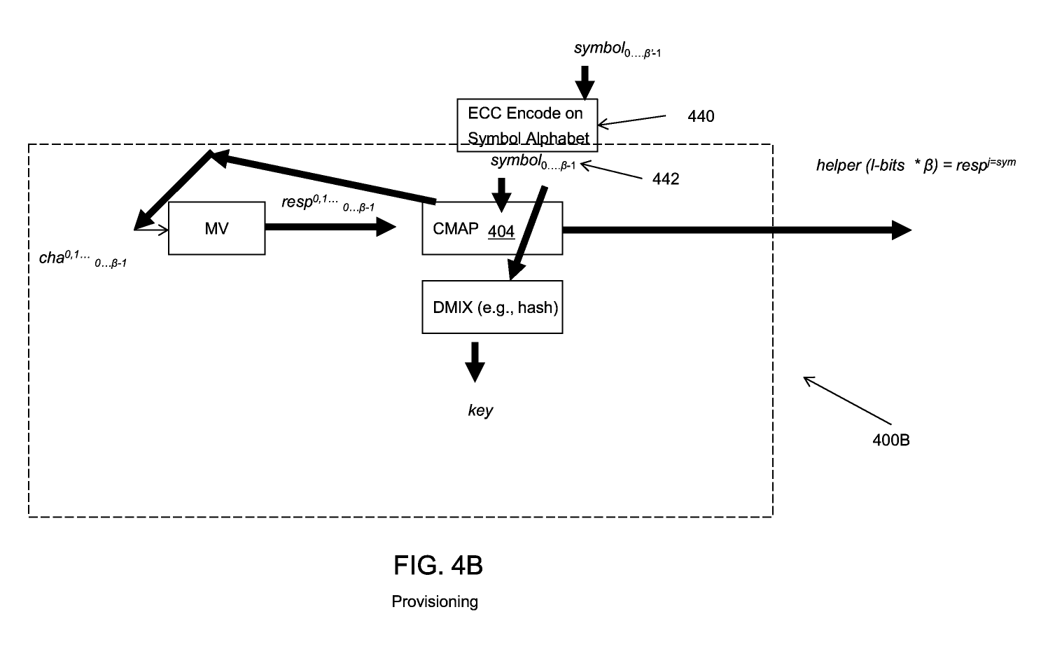

Referring now to FIG. 4, a system 400 is shown for key provisioning in accordance with various aspects of the present invention. The system 400 includes a down-mix function module (DMIX) 402. In accordance with various aspects of the present invention, the DMIX 402 can use a function including a cryptographic, a universal hash function, or an LFSR, which is added to distill the β symbols comprising of β×log₂(w) bits into a key 406 of a smaller number of bits. The key 406 (e.g., a 128-bit or 256-bit AES key) can be used with conventional cryptographic blocks; the key 406 is dynamically generated from manufacturing variations, as determined by a MVU 408, when needed, in accordance with various aspects of the present invention, as opposed to statically and persistently stored in e-fuse or other non-volatile storage mechanisms.

Referring now to FIG. 4B, in accordance with various aspects of the present invention, the system 400B includes conventional error correction encoding approaches. For example, an error correction encoder 440 that operates on an alphabet (symbol) can precede the CMAP 404 (constellation mapper) to produce additional parity “symbols” that is present in 442.

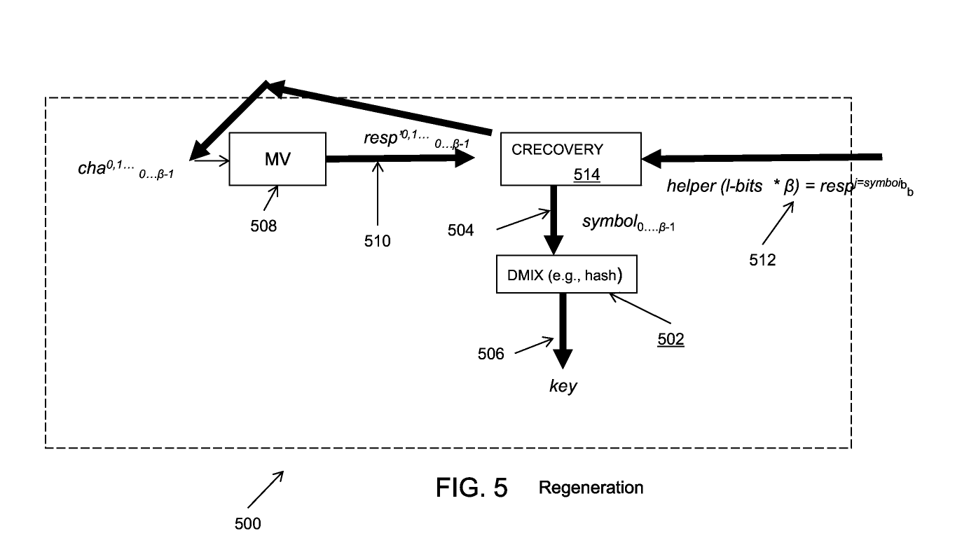

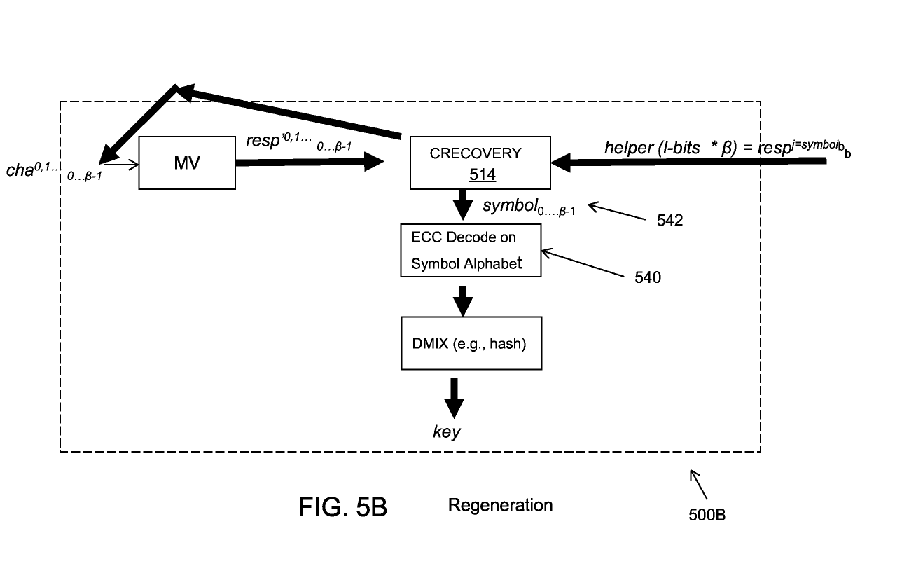

Referring now to FIG. 5, in accordance with various aspects of the present invention, a system 500 shows the key regeneration process, where a down-mix function (DMIX) 502, for example a cryptographic or a universal hash function or an LFSR, is added to distill the β symbols comprising of β×log₂(w) bits into a key 506 of a smaller number of bits. The key 506 (e.g., a 128-bit or 256-bit AES key) can be used with conventional cryptographic blocks; the key 506 is dynamically generated from manufacturing variations, as determined by a MVU 508 when needed as opposed to statically and persistently stored in e-fuse or other non-volatile storage mechanisms. The response readings 510 from manufacturing variation readings are noisy (these are physical readings) and the helper data 512 helps to recover (the original) symbols 504 using, in accordance with various aspects of the present invention, an for example “optimal” decoding method in the form of maximum likelihood recovery that included in the CRECOVERY unit 514 (including a constellation recovery function).

Referring now to FIG. 5B, in accordance with various aspects of the present invention, a system 500B is shown that includes an error correction decoder module 540. The module 540 operates on an alphabet (symbol) 542 and can be placed following the CRECOVERY unit 514 to “mop up” residual noise.

To elaborate further, in accordance with one aspect of the present invention, the CRECOVERY unit 514 can use a maximum likelihood decoder, an example one such aspect being shown in FIG. 3, wherein the theoretical best performance of constellation points recovery is achieved (assuming the original symbols are uniformly distributed).

In accordance with another aspect of the present invention, the constellation demodulation can use a list decoder, wherein not only the most likely points, but next most likely point or the next-next most likely point, etc. can be selected, to improve noise tolerance due to environmental changes (temperature, voltage, aging) or small manufacturing process geometries, with the aid of additional error detection or error control circuitry.

In accordance with various aspects of the present invention, list decoding can follow the maximum likelihood logic, although list decoding using non-maximum likelihood is also possible in accordance with various aspects of the present invention. Furthermore and in accordance with one aspect of the present invention, the error detection can be added to any of the aspects of the present invention, including constellation demodulation using any of the aspects of the present invention. In accordance with one aspect of the present invention, the error correction can be added any of the aspects of the present invention, including constellation demodulation using any of the aspects of the present invention.

Referring again to FIG. 1C, in accordance with various aspects of the present invention, four silicon PUFs are included in the MVU 124, so they are on the same device or system 122. For a predictable challenge schedule, one of 2⁸=256 PUF response choices are selected, and the response bits from the four silicon PUFs are bit-wise XORed. Maximum likelihood recovery is used to recover the original constellation point (response), of which there are 256 choices corresponding to the encoding of 8 secret keying bits. Here, each symbol being encoded and later recovered is 8-bits. This is in contrast with how PUF bits are normally treated in the context of PUF Key Generation's error correction process, where each PUF bit is treated effectively as a single-bit symbol (instead of a multi-bit symbol) to form an error correction codeword.

The different constellation points can be formed by a combination of different PUFs on the same device, from different challenge selections, from using different combination or mixing or scrambling or modulation functions, etc. The list decoding stage can decode so that the maximum likely, second most likely, third most likely etc., response are recovered, and the correct one can be selected depending on error detection flags such as parity error detection. In accordance with the various aspects of the present invention, constellation modulation modes/modalities deriving multiple-bit symbols can be based on one or combinations of:

1. PUF selection (Multiple Arbiter PUFs, Multiple Ring Oscillator PUFs, Multiple Memory PUFs, or combinations of these. More generally physical pseudo-random functions with manufacturing variations, including biometrics, paper or paint surfaces, passport photos, etc.).

2. Code selection (e.g., Walsh Code, Gold Code, m-sequence)

3. Challenge selection (including challenge inversion, challenge mixed with code, challenge derived from different polynomials, challenge with error correction encoding). Challenge can use hash function, LFSR, combinations of these.

4. Choice of mixing functions, including XOR, majority function, addition, modulo addition.

In accordance with the various aspects of the present invention, a traditional error correction approach can be cascaded, using the maximum-likelihood and optionally list-decoding stage as a “first” stage noise reduction.

In the realm of silicon PUFs, based on the various aspects of the present invention, the method can be applied to many popular silicon PUF types, including Arbiter PUF, Ring Oscillator PUF, and memory PUFs.

Where a range of values is provided, it is understood that each intervening value, to the tenth of the unit of the lower limit unless the context clearly dictates otherwise, between the upper and lower limit of that range and any other stated or intervening value in that stated range, is encompassed within the invention. The upper and lower limits of these smaller ranges may independently be included in the smaller ranges and are also encompassed within the invention, subject to any specifically excluded limit in the stated range. Where the stated range includes one or both of the limits, ranges excluding either or both of those included limits are also included in the invention.

Unless defined otherwise, all technical and scientific terms used herein have the same meaning as commonly understood by one of ordinary skill in the art to which this invention belongs. Although any methods and materials similar or equivalent to those described herein can also be used in the practice or testing of the present invention, representative illustrative methods and materials are now described.

All publications and patents cited in this specification are herein incorporated by reference as if each individual publication or patent were specifically and individually indicated to be incorporated by reference and are incorporated herein by reference to disclose and describe the methods and/or materials in connection with which the publications are cited. The citation of any publication is for its disclosure prior to the filing date and should not be construed as an admission that the present invention is not entitled to antedate such publication by virtue of prior invention. Further, the dates of publication provided may be different from the actual publication dates which may need to be independently confirmed.

It is noted that, as used herein and in the appended claims, the singular forms “a”, “an”, and “the” include plural referents unless the context clearly dictates otherwise. It is further noted that the claims may be drafted to exclude any optional element. As such, this statement is intended to serve as antecedent basis for use of such exclusive terminology as “solely,” “only” and the like in connection with the recitation of claim elements, or use of a “negative” limitation.

As will be apparent to those of skill in the art upon reading this disclosure, each of the individual embodiments described and illustrated herein has discrete components and features which may be readily separated from or combined with the features of any of the other several embodiments without departing from the scope or spirit of the present invention. Any recited method can be carried out in the order of events recited or in any other order which is logically possible.

Although the foregoing invention has been described in some detail by way of illustration and example for purposes of clarity of understanding, it is readily apparent to those of ordinary skill in the art in light of the teachings of this invention that certain changes and modifications may be made thereto without departing from the spirit or scope of the appended claims.

Accordingly, the preceding merely illustrates the principles of the invention. It will be appreciated that those skilled in the art will be able to devise various arrangements which, although not explicitly described or shown herein, embody the principles of the invention and are included within its spirit and scope. Furthermore, all examples and conditional language recited herein are principally intended to aid the reader in understanding the principles of the invention and the concepts contributed by the inventors to furthering the art, and are to be construed as being without limitation to such specifically recited examples and conditions. Moreover, all statements herein reciting principles, aspects, and embodiments of the invention as well as specific examples thereof, are intended to encompass both structural and functional equivalents thereof.

Additionally, it is intended that such equivalents include both currently known equivalents and equivalents developed in the future, i.e., any elements developed that perform the same function, regardless of structure. The scope of the present invention, therefore, is not intended to be limited to the exemplary embodiments shown and described herein. Rather, the scope and spirit of present invention is embodied by the appended claims.

In accordance with the teaching of the present invention and certain embodiments, a computer device is an article of manufacture. Examples of an article of manufacture include: an electronic component residing on a mother board, a server, a mainframe computer, a mobile telephone, a multimedia-enabled smartphone, a tablet computer, a personal digital assistant, a personal computer, a laptop, a set-top box, an MP3 player, an email enabled device, a web enabled device, or other special purpose computer each having one or more processors (e.g., a Central Processing Unit, a Graphical Processing Unit, or a microprocessor) that is configured to execute a computer readable program code (e.g., an algorithm, hardware, firmware, and/or software) to receive data, transmit data, store data, or perform methods.

The article of manufacture (e.g., computing device) includes a non-transitory computer readable medium having a series of instructions, such as computer readable program steps encoded therein. In certain embodiments, the non-transitory computer readable medium includes one or more data repositories.

In certain embodiments and in accordance with any aspect of the present invention, computer readable program code is encoded in a non-transitory computer readable medium of the computing device. The processor, in turn, executes the computer readable program code to create or amend an existing computer-aided design using a tool. In other embodiments, the creation or amendment of the computer-aided design is implemented as a web-based software application in which portions of the data related to the computer-aided design or the tool or the computer readable program code are received or transmitted to a computing device of a host. A controller is meant to represent a control element for the invention, which manages local processes within the battery and communicates these or the results of these to an external control system. The controller can be implemented in a variety of ways:
with one or more distinct microprocessors, volatile and/or non-volatile memory and peripherals or peripheral controllers;
with an integrated microcontroller, which has a processor, local volatile and non-volatile memory, peripherals and input/output pins;
discrete logic which implements a fixed version of the control system;
programmable logic which implements a version of the control system which can be reprogrammed either through a local or remote interface. Such logic could implement either a control system either in logic or via a set of commands executed by a soft-processor.

In certain embodiments based on the various aspects of the present invention, reference is made to communication between two electronic components. In certain embodiments, the communication fabric contains either or both wired or wireless connections for the transmission of signals including electrical connections, magnetic connections, or a combination thereof.

In certain embodiments, the system includes a hardware-based module (e.g., a digital signal processor (DSP), a field programmable gate array (FPGA)) and/or a software-based module (e.g., a module of computer code, a set of processor-readable instructions that are executed at a processor). In some embodiments, one or more of the functions associated with the system is performed, for example, by different modules and/or combined into one or more modules locally executable on one or more computing devices.

Accordingly, the preceding merely illustrates the various aspects and principles of the present invention. It will be appreciated that those skilled in the art will be able to devise various arrangements which, although not explicitly described or shown herein, embody the principles of the invention and are included within its spirit and scope. Furthermore, all examples and conditional language recited herein are principally intended to aid the reader in understanding the principles of the invention and the concepts contributed by the inventors to furthering the art, and are to be construed as being without limitation to such specifically recited examples and conditions. Moreover, all statements herein reciting principles, aspects, and embodiments of the invention as well as specific examples thereof, are intended to encompass both structural and functional equivalents thereof. Additionally, it is intended that such equivalents include both currently known equivalents and equivalents developed in the future, i.e., any elements developed that perform the same function, regardless of structure. The scope of the present invention, therefore, is not intended to be limited to the exemplary embodiments shown and described herein. Rather, the scope and spirit of present invention is embodied by the appended claims.

What is claimed is:

1. A device comprising:
a manufacturing variation unit (MVU) to receive at least one challenge and generate at least one response, wherein the MVU produces physical manufacturing variation readings; and
a symbol mapping unit including at least one input to receive at least one symbol and at least one interface to the MVU,
wherein the symbol mapping unit maps the at least one symbol onto the physical manufacturing variation readings to produce an output series of bits that depend on the at least one symbol and the physical manufacturing variation readings.

2. The device of claim 1, wherein the symbol includes a single bit.

3. The device of claim 1, wherein the symbol includes two bits.

4. The device of claim 1, wherein the symbol includes three or more bits.

5. The device of claim 1, wherein the MVU comprises a plurality of PUF circuits and the mapping is a function of the plurality of PUF circuits.

6. The device of claim 5, wherein the function selects at least one PUF circuit from the plurality of PUF circuits.

7. The device of claim 1, wherein the mapping is a function of one or more responses.

8. The device of claim 1, wherein the mapping is a function of one or more responses manipulated using XOR scrambling codes.

9. The device of claim 7, wherein the function includes using Walsh codes on one or more responses.

10. The device of claim 7, wherein the function includes using Gold codes on one or more responses.

11. The device of claim 7, wherein the function includes using m-sequences on one or more responses.

12. The device of claim 1, wherein the mapping is a function of a plurality of challenges.

13. The device of claim 12, wherein the function selects challenge sequences arising from selection of seed challenges.

14. The device of claim 12, wherein the function modulates a derived challenge sequence based on one or more symbols.

15. The device of claim 1, further comprising a recovery unit in communication with the mapping unit to receive an output of the mapping unit.

16. A device comprising:
a manufacturing variations unit (MVU) to receive one or more challenges and generate one or more responses, wherein the MVU produces physical manufacturing variation readings;
a symbol recovery unit including helper data input and in communication with the MVU, where the symbol recovery unit recovers a symbol.

17. The device of claim 16, wherein the symbol is a single bit and equivalent to BPSK demodulation.

18. The device of claim 16, wherein the symbol is two bits and equivalent to QPSK demodulation.

19. The device of claim 16, wherein the symbol is three or more bits for higher order demodulation.

20. The device of claim 16, wherein the MVU comprises a plurality of PUF circuits and the recovery is based on selection of at least one PUF circuit from a plurality of PUF circuits.

21. The device of claim 16, wherein the recovery is based on a plurality of scrambling selection codes.

22. The device of claim 16, wherein the recovery is based on selection from different challenge selection.

23. The device of claim 16, wherein decoded symbol distances are used in the recovery.

24. The device of claim 16, wherein list-decoding is used to look at a first-most-likely symbol and the next-most-likely symbol, with the symbol choice being based on an error control mechanism.

25. The device of claim 16, wherein list-decoding is used to look at a first-most-likely symbol and a ranking of other likely symbol candidates, with a symbol choice being based on an error control mechanism.

26. The device of claim 16, wherein the recovery is based on maximum likelihood detection.

27. The device of claim 16, wherein the recovery is based on threshold-based detection.

28. The device of claim 16, wherein a downmix function is used to produce a key from the symbol.
